(19) United States
(12) Patent Application Publication
(10) Pub. No.: US 2003/0007586 A1
(43) Pub. Date: Jan. 9, 2003

(54) Phase locked loop circuit

(76) Inventor: Yoshikazu Ishii, Yokohama-shi (JP)

Correspondence Address: LOUIS WOO, LAW OFFICE OF LOUIS WOO, 1901 NORTH FORT MYER DRIVE, SUITE 501, ARLINGTON, VA, 22209, US

(21) Appl. No.: 10/189,771

(22) Filed: Jul. 8, 2002

(30) Foreign Application Priority Data
Jul. 9, 2001 (JP) 2001-207958

(51) Int. Cl. H03D 3/24

(52) U.S. Cl. 375/376

(57) ABSTRACT

In a PLL circuit including a phase comparator for comparing an output of a voltage controlled oscillator with a reference signal to control a voltage to the voltage controlled oscillator on the basis of an output of the phase comparator, passed through a low pass filter, so that the output of the voltage controlled oscillator and the reference signal agree with each other, a band pass filter is further provided in a former stage of the phase comparator for reducing noise components contained in a the reference signal. The band pass filter has a bandwidth corresponding to a frequency/phase variation range of the reference signal. This circuit arrangement can sufficiently reduce the noise component contained in the reference signal inputted to the PLL loop, and provides an output signal of the voltage controlled oscillator which shows a high follow-up characteristic with respect to the frequency/phase variation of the reference signal and has less jitter at the PLL locked condition even if much noise exists in the reference signal.

### BACKGROUND OF THE INVENTION

1. Field of the Invention

The present invention relates to a phase locked loop circuit (which will be referred to hereinafter as a “PLL circuit”) designed to compare an output of a voltage controlled oscillator with a reference signal through the use of a phase comparator for controlling the voltage to be applied to the voltage controlled oscillator on the basis of an output of the phase comparator so that both agree with each other.

2. Description of the Related Art

As a conventional PLL circuit, there has been known a circuit disclosed in, for example, Japanese Unexamined Patent Publication No. HEI 01-232828. FIG. 11 is a block diagram showing an arrangement of the conventional PLL circuit. In FIG. 11, the conventional PLL circuit includes a phase comparator 2, a low pass filter (LPF) 3 and a voltage controlled oscillator (VCO) 4, and an output of the voltage controlled oscillator 4 is compared with a reference signal in the phase comparator 2 to control the voltage controlled oscillator 4 on the basis of an output of the phase comparator 2 which passes through the low pass filter 3 so that the output of the voltage controlled oscillator 4 agrees with the reference signal, with the voltage controlled oscillator 4 being made to output a signal synchronized in frequency and phase with the reference signal.

However, in the case of the conventional PLL circuit arrangement, if a noise component is introduced into the reference signal, particularly, when the amount of noise is large, there is a problem that phase fluctuation (jitter) occurs in a signal from the voltage controlled oscillator 4 due to the noise. In addition, if the frequency/phase variation exists in the reference signal and the bandwidth of the low pass filter 3 in the PLL loop is made narrower for the reduction of the jitter, the follow-up of the reference signal with respect to the frequency/phase variation degrades.

### SUMMARY OF THE INVENTION

The present invention has been developed with a view to eliminating these problems, and it is therefore an object of the invention to provide a PLL circuit capable of reducing the jitter of a signal outputted from a voltage controlled oscillator by reducing the noise component contained in a reference signal constituting a PLL loop input.

For this purpose, in accordance with an aspect of the present invention, in a PLL circuit comprising a phase comparator for comparing an output of a voltage controlled oscillator with a reference signal to control a voltage to the voltage controlled oscillator on the basis of an output of the phase comparator, passed through a low pass filter, so that the output of the voltage controlled oscillator and the reference signal agree with each other, a band pass filter is provided in a former (previous) stage of the phase comparator.

This circuit arrangement can reduce the noise component contained in the reference signal inputted to the PLL loop, thus reducing the jitter of a signal to be outputted from the voltage controlled oscillator.

In addition, in this configuration, the band pass filter is a variable bandwidth band pass filter and the low pass filter is a variable bandwidth low pass filter, and a control unit is provided for controlling the bandwidths thereof, with the control unit being made to control the bandwidths of the variable bandwidth band pass filter and the variable bandwidth low pass filter on the basis of an amount of noise contained in a reference signal.

This arrangement can reduce the noise component contained in the reference signal inputted to the PLL loop, thereby reducing the jitter of a signal to be outputted from the voltage controlled oscillator.

Still additionally, in accordance with another aspect of the present invention, in a PLL circuit comprising a phase comparator for comparing an output of a voltage controlled oscillator with a reference signal to control a voltage to the voltage controlled oscillator on the basis of an output of the phase comparator, passed through a low pass filter, so that the output of the voltage controlled oscillator and the reference signal agree with each other, the voltage controlled oscillator comprises a plurality of voltage controlled oscillators different in voltage-frequency sensitivity from each other, and a selection control unit is further provided for selecting outputs of these voltage controlled oscillators, with the selection control unit being made to select the outputs of the plurality of voltage controlled oscillators on the basis of an amount of noise contained in the reference signal for changing the gain of the PLL loop.

This arrangement can make the switching among the voltage controlled oscillators having various types of voltage-frequency sensitivities to control the loop gain of the PLL loop, which reduces the noise component contained in the reference signal inputted to the PLL loop, thus reducing the jitter of a signal to be outputted from the voltage controlled oscillator.

Moreover, in this configuration, a band pass filter is provided in a former stage of the phase comparator. This arrangement can reduce the noise component contained in the reference signal inputted to the PLL loop through the use of the band pass filter, and can control the loop gain of the PLL loop by making the switching among the voltage controlled oscillators having various types of voltage-frequency sensitivities, thus reducing the noise component contained in the reference signal inputted to the PLL loop to reduce the jitter of a signal to be outputted from the voltage controlled oscillator.

Still moreover, in this configuration, the band pass filter is a variable bandwidth band pass filter and the low pass filter is a variable bandwidth low pass filter, and the selection control unit being made to control the bandwidths of the variable bandwidth band pass filter and the variable bandwidth low pass filter on the basis of an amount of noise contained in the reference signal.

This arrangement can reduce the noise component contained in the reference signal inputted to the PLL loop and can reduce the jitter of a signal to be outputted from the voltage controlled oscillator.

Furthermore, in accordance with a further aspect of the present invention, in a PLL circuit comprising a phase comparator for comparing an output of a voltage controlled oscillator with a reference signal to control a voltage to the voltage controlled oscillator on the basis of an output of the phase comparator, passed through a low pass filter, so that the output of the voltage controlled oscillator and the reference signal agree with each other, a variable gain amplifier is provided in a latter (subsequent) stage of the phase comparator and a control unit is provided for controlling the variable gain amplifier, with the control unit being designed to control the gain of the variable gain amplifier on the basis of an amount of noise contained in the reference signal for changing the PLL loop gain.

This arrangement can control the loop gain of the PLL loop by changing the amplification degree of the variable gain amplifier, which reduces the noise component contained in a reference signal inputted to the PLL loop to reduce the jitter of a signal to be outputted from the voltage controlled oscillator.

Still furthermore, in this configuration, a band pass filter is provided in a former stage of the phase comparator. This arrangement can reduce the noise component contained in the reference signal inputted to the PLL loop and can reduce the jitter of a signal to be outputted from the voltage controlled oscillator.

Moreover, in this configuration, the band pass filter is a variable bandwidth band pass filter and the low pass filter is a variable bandwidth low pass filter, and the control unit is made to control the bandwidths of the variable bandwidth band pass filter and the variable bandwidth low pass filter on the basis of an amount of noise contained in the reference signal.

This arrangement can reduce the noise component contained in the reference signal inputted to the PLL loop, thereby reducing the jitter of a signal to be outputted from the voltage controlled oscillator.

### BRIEF DESCRIPTION OF THE DRAWINGS

Other objects and features of the present invention will become more readily apparent from the following detailed description of the preferred embodiments taken in conjunction with the accompanying drawings in which:

FIG. 1 is a block diagram showing an arrangement of a PLL circuit according to a first embodiment of the present invention;

FIG. 2 is an illustration of one example of a characteristic of a band pass filter for use in the present invention;

FIG. 3 is a block diagram showing an arrangement of a PLL circuit according to a second embodiment of the present invention;

FIG. 4 is an illustration of one example of a characteristic of a variable bandwidth band pass filter for use in the present invention, and of a noise reducing method using a filter;

FIG. 5 is a block diagram showing an arrangement of a PLL circuit according to a third embodiment of the present invention;

FIG. 6 is a block diagram showing an arrangement of a PLL circuit according to a fourth embodiment of the present invention;

FIG. 7 is a block diagram showing an arrangement of a PLL circuit according to a fifth embodiment of the present invention;

FIG. 8 is a block diagram showing an arrangement of a PLL circuit according to a sixth embodiment of the present invention;

FIG. 9 is a block diagram showing an arrangement of a PLL circuit according to a seventh embodiment of the present invention;

FIG. 10 is a block diagram showing an arrangement of a PLL circuit according to an eighth embodiment of the present invention; and

FIG. 11 is an illustration of an arrangement of a conventional PLL circuit.

### DESCRIPTION OF THE PREFERRED EMBODIMENTS

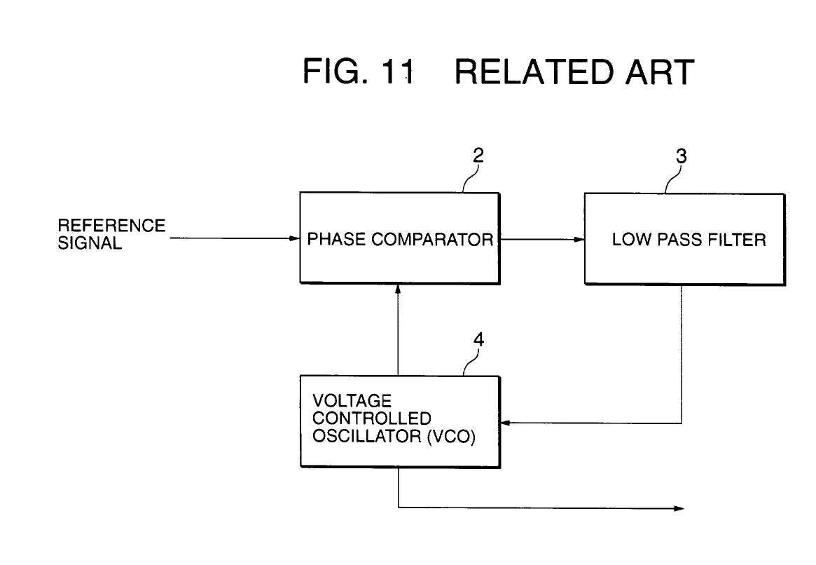

Embodiments of the present invention will be described hereinbelow with reference to the drawings. In the description of these embodiments, the same parts as or parts corresponding to those of the above-described conventional example shown in FIG. 11 will be marked with the same reference numerals, and the detailed description thereof will be omitted for brevity.

(First Embodiment)

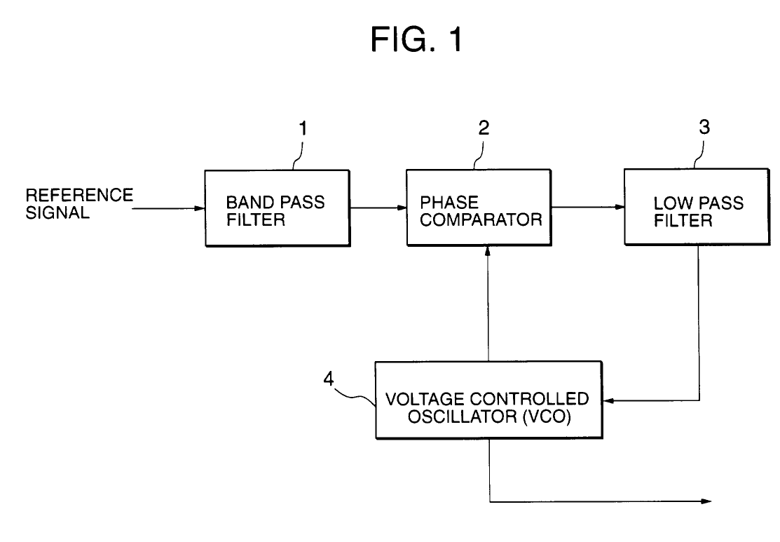

FIG. 1 is a block diagram showing an arrangement of a PLL circuit according to a first embodiment of the present invention. The difference of the PLL circuit according to the first embodiment shown in FIG. 1 from the conventional example shown in FIG. 11 is that a band pass filter 1 is provided in a former stage of a phase comparator 2.

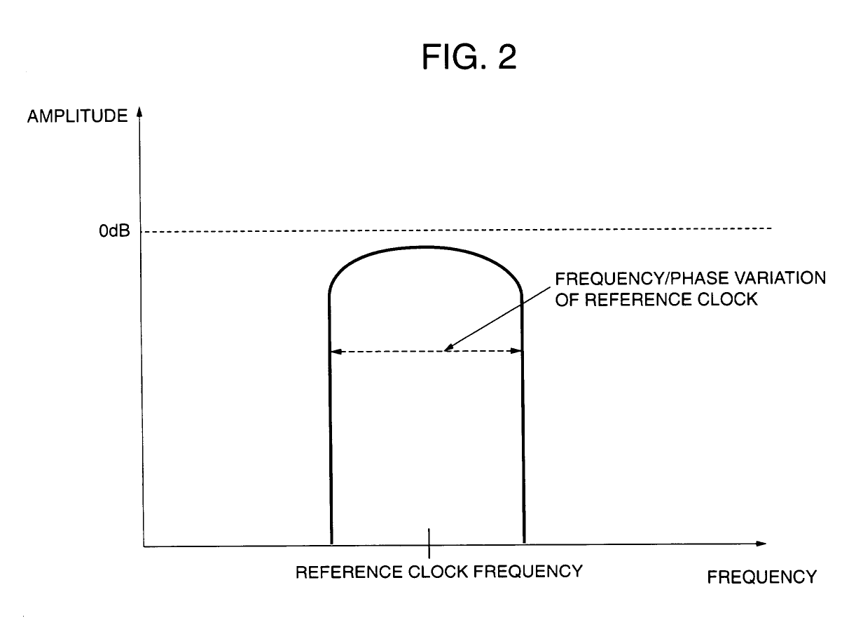

Referring to FIGS. 1 and 2, a description will be given hereinbelow of an operation of this PLL circuit according to the first embodiment.

In FIG. 1, when a reference signal including noise is inputted to a PLL loop, a band pass filter 1 is made to eliminate the noise components. In this case, the band pass filter 1 has a characteristic shown in FIG. 2. As FIG. 2 shows, this filter characteristic is a steep frequency characteristic capable of securing a bandwidth which can accept a frequency/phase variation of a reference signal forming a follow-up object while removing noise components which are out of the frequency/phase variation range of the reference signal.

After the removal of the noise components which are out of the frequency/phase variation range by the band pass filter 1, the reference signal is fed to a phase comparator 2 to be compared in phase with a signal from a voltage controlled oscillator (VCO) 4. As the comparison result, the phase comparator 2 outputs a voltage corresponding (proportional) to the difference signal therebetween. This voltage passes through a low pass filter 3 and then enters the VCO 4 as a drive voltage.

Thus, although the use of only the low pass filter 3 in the PLL loop cannot achieve the sufficient removal of the high-frequency noise components, the additional employment of the band pass filter 1 with a steep frequency characteristic shown in FIG. 2 can sufficiently remove the noise components introduced into the reference signal constituting the PLL loop input. This can achieve the reduction of the jitter of an output signal of the VCO 4 stemming from the noise components contained in the inputted reference signal.

As described above, according to the first embodiment, the band pass filter 1 provided in the former stage of the phase comparator 2 removes the noise components in unnecessary bands, existing in the reference signal forming the PLL loop input, other than or above the frequency/phase variation range of the reference signal forming the follow-up object, thus reducing the jitter of a signal to be outputted from the voltage controlled oscillator 4 to realize a PLL circuit with less jitter even if much noise exists in the reference signal.

(Second Embodiment)

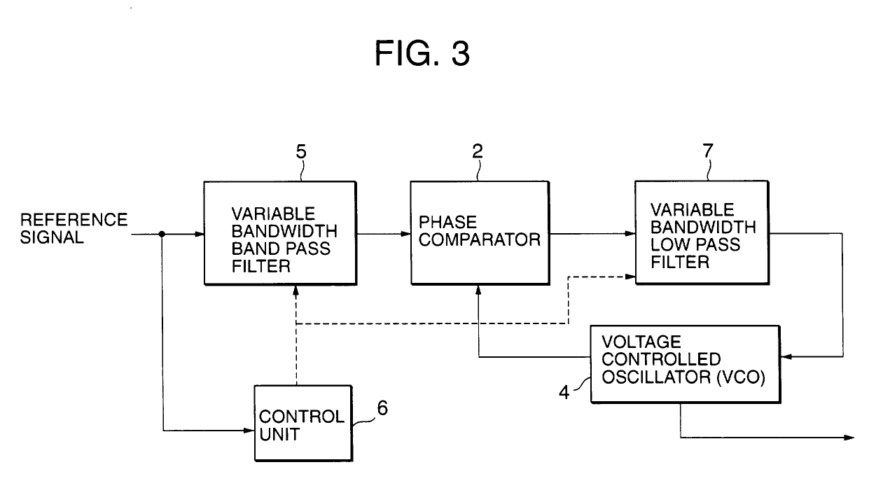

FIG. 3 is a block diagram showing an arrangement of a PLL circuit according to a second embodiment of the present invention. In the second embodiment, the band pass filter in the circuit arrangement according to the first embodiment shown in FIG. 1 is replaced with a variable bandwidth band pass filter 5 and the low pass filter 3 therein is replaced with a variable bandwidth low pass filter 7. A control unit 6 is further provided for controlling these filters 5 and 7.

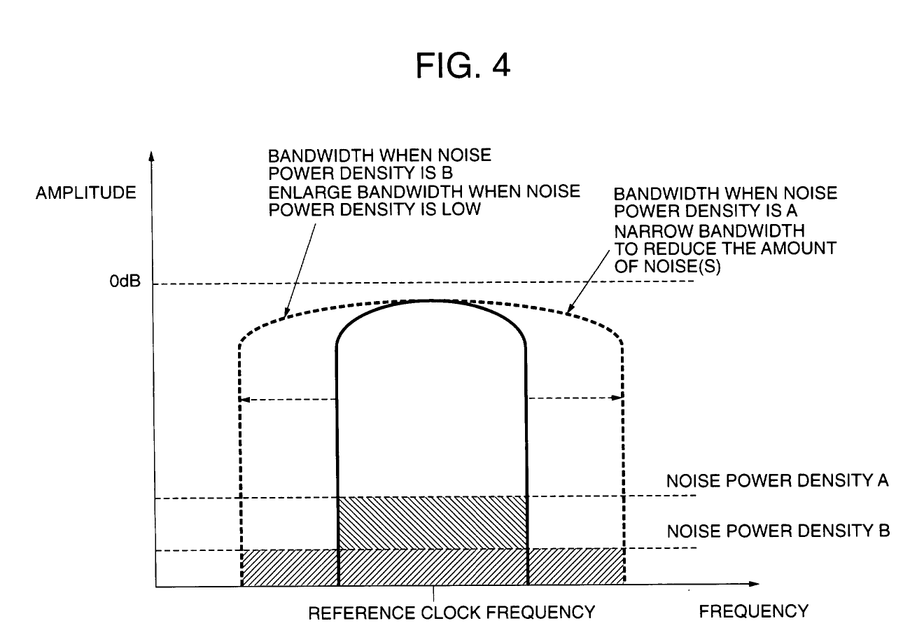

Referring to FIGS. 3 and 4, a description will be given hereinbelow of an operation of the PLL circuit thus arranged.

When a reference signal containing noise is inputted to the PLL loop, the variable bandwidth band pass filter 5 removes that noise components. FIG. 4 shows the characteristic of the variable bandwidth band pass filter 5. The passband of the variable bandwidth band pass filter 5 is controlled through the use of a density of noise power contained in the reference signal. That is, if the noise power density contained in the reference signal is low (noise power density B in FIG. 4), the jitter of an output signal of the VCO 4 stemming from the noise components introduced into the inputted reference signal does not reach a large value, so the passband width is enlarged to widen the followable frequency/phase variation band on the reference signal.

On the other hand, if the noise power density contained in the reference signal is high (noise power density A in FIG. 4), the jitter of an output signal of the VCO 4 stemming from the noise components introduced into the inputted reference signal increases, so the passband width is reduced to lower the jitter of the VCO output signal originating from the noise components introduced into the inputted reference signal.

The noise component removed reference signal from the variable bandwidth band pass filter 5 is compared in phase with a signal from the VCO 4 in the phase comparator 2, and the phase comparator 2 outputs a voltage corresponding to (proportional to) the difference signal therebetween. This voltage undergoes further removal of the noise components when passing through the variable bandwidth low pass filter 7.

In this arrangement, as well as the variable bandwidth band pass filter 5, the passband of the variable bandwidth low pass filter 7 is widened when the density of noise power contained in the reference signal is low, for that the jitter of the VCO output signal originating from the noise components introduced into the inputted reference signal is not large. This enlarges the followable reference signal frequency/phase variation band.

On the other hand, if the density of noise power contained in the reference signal is high, the jitter of the VCO output signal originating from the noise components introduced into the inputted reference signal increases. For this reason, the jitter of the VCO output signal due to the noise components of the inputted reference signal is reduced by decreasing the passband width of the variable bandwidth low pass filter 7. The noise component removed voltage is given to the VCO 4 to function as a drive voltage.

Thus, although only the variable bandwidth low pass filter 7 cannot achieve the sufficient removal of the high-frequency noise components, the additional employment of the variable bandwidth band pass filter 7 can sufficiently achieve the sufficient removal of the noise components introduced into the reference signal constituting the PLL loop input. This can achieve the reduction of the jitter of an output signal of the VCO 4 stemming from the noise components contained in the inputted reference signal.

In this configuration, the control unit 6 is designed to control the passband of the variable bandwidth band pass filter 5 and/or the variable bandwidth low pass filter 7 in accordance with a density of noise power contained in the reference signal. This control operation of the control unit 6 can enlarge the followable frequency/phase variation range on the reference signal while maintaining the jitter occurring due to noise to a allowable constant value.

As described above, according to the second embodiment, the variable bandwidth band pass filter 5 provided in the former stage of the phase comparator 2 removes the noise components in unnecessary bands, existing in the reference signal forming the PLL loop input, other than the frequency/phase variation range of the reference signal forming the follow-up object, thus reducing the jitter of a signal to be outputted from the voltage controlled oscillator 4 to realize a PLL circuit with less jitter even if much noise exists in the reference signal.

In addition, since the passband of the variable bandwidth band pass filter 5 and/or the variable bandwidth low pass filter 7 is controlled in accordance with a density of noise power contained in a reference signal, it is possible to enlarge the followable frequency/phase variation range on the reference signal while reducing the jitter occurring due to noise, thus realizing a PLL circuit which maximizes the followable reference signal frequency/phase variation range in accordance with the amount of noise introduced into the reference signal in a state where the jitter arising due to noise is kept to a constant allowable level.

(Third Embodiment)

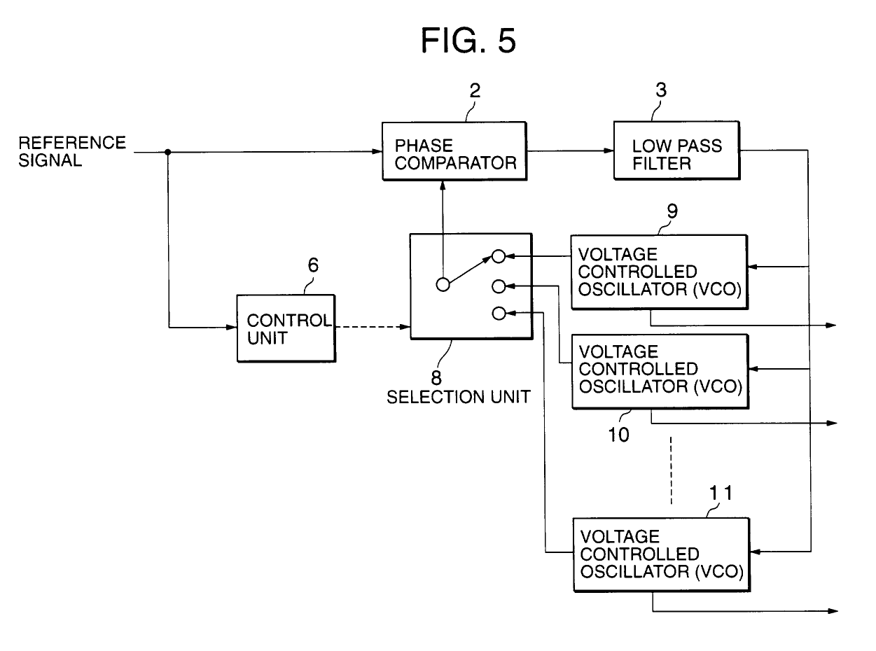

FIG. 5 is a block diagram showing an arrangement of a PLL circuit according to a third embodiment of the present invention. In the PLL circuit arrangement according to the third embodiment, a plurality of voltage controlled oscillators (VCO) 9, 10 and 11 are provided and a selection unit 8 is provided to selectively carry out the switching among the outputs of these VCOs 9 to 11.

Referring to FIG. 5, a description will be given hereinbelow of an operation of the PLL circuit according to the third embodiment.

A reference signal including noise, inputted to the PLL loop, is compared in phase with a signal from a group of voltage controlled oscillators (VCOs) 9 to 11 in a phase comparator 2, and the phase comparator 2 outputs a voltage corresponding to (proportional to) the difference signal therebetween. This voltage passes through a low pass filter 3, where its noise components are removed therefrom. The voltage after the removal of the noise components is fed as a drive voltage to the VCO group.

In this configuration, as FIG. 5 shows, a plurality of VCOs 9 to 11 constituting the VCO group are provided which are made to have different voltage-frequency sensitivities, and the gain of the PLL loop is changed through the selection or switching among these VCOs 9 to 11 with the different voltage-frequency sensitivities. For the selection among the VCOs 9 to 11 to change the loop gain, a selection unit 8 is placed between these VCOs 9 to 11 and the phase comparator 2. For example, for increasing the loop gain, the selection unit 8 selects the output of a VCO (one of the plurality of VCOs 9 to 11) with a high voltage-frequency sensitivity, and for decreasing the loop gain, the selection unit 8 selects the output of a VCO (one of the plurality of VCOs 9 to 11) with a low voltage-frequency sensitivity. The selection unit 8 is controlled by a control unit 6, and the control unit 6 is designed to control the selection unit 8 in accordance with a noise power density (the amount of noise) contained in a reference signal inputted. In this connection, the control unit 6 and the selection unit 8 constitute a selection control unit for a change of the PLL loop gain.

A description will be given hereinbelow of a loop gain changing method, that is, VCO output selecting method.

A change of the loop gain causes a change of the follow-up characteristic with respect to the frequency/phase variation of the inputted reference signal. For the improvement of the follow-up characteristic, there is a need to increase the loop gain. On the other hand, the increase in the loop gain can increase the jitter of the VCO output occurring due to a noise component contained in the reference signal.

Accordingly, when the noise power density contained in the reference signal is low, since the jitter of the VCO output signal stemming from the noise component introduced into the inputted reference signal is not large, the output of a VCO with a high voltage-frequency sensitivity is selected to increase the loop gain. This can provide higher follow-up characteristic with respect to the frequency/phase variation of the reference signal.

On the other hand, when the noise power density contained in the reference signal is high, since the jitter of the VCO output signal stemming from the noise component introduced into the inputted reference signal becomes large, the output of a VCO with a low voltage-frequency sensitivity is selected to decrease the loop gain. This can reduce the jitter of the VCO output signal stemming from the noise components of the inputted reference signal.

Thus, the selection among the outputs of the VCOs with different voltage-frequency sensitivities controls the PLL loop gain, which can provide high follow-up characteristic with respect to the frequency/phase variation of a reference signal while reducing the jitter due to the noise introduced into the reference signal.

As described above, according to the third embodiment, the PLL loop gain is controlled through the selection of one of the outputs of the VCOs with different voltage-frequency sensitivities so that the higher follow-up characteristic is obtainable with respect to the frequency/phase variation of a reference signal while the less jitter due to the noise of the reference signal is achievable, thus realizing a PLL circuit which maximizes the followable reference signal frequency/phase variation range in accordance with the amount of noise contained in the reference signal while maintaining the jitter due to the noise to a constant allowable level.

(Fourth Embodiment)

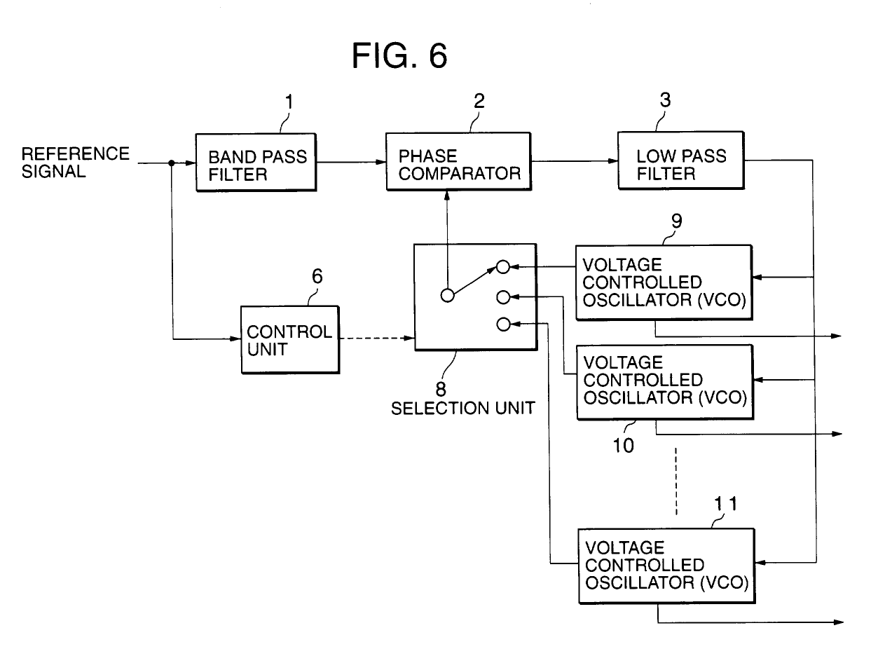

FIG. 6 is a block diagram showing an arrangement of a PLL circuit according to a fourth embodiment of the present invention. The fourth embodiment relates to a combination of the circuit arrangement according to the first embodiment and the circuit arrangement according to the third embodiment, that is, in the arrangement according to the third embodiment, a band pass filter 1 is provided in a former stage of the phase comparactor 2.

Referring to FIG. 6, a description will be given hereinbelow of an operation of the PLL circuit according to the third embodiment.

A reference signal including noise, inputted to the PLL loop, passes through the band pass filter 1, where the elimination of its noise components takes place. The band pass filter 1 has a characteristic shown in FIG. 2, that is, a steep frequency characteristic which can secure a bandwidth which can provide for the frequency/phase variation of the reference signal forming a follow-up object but which copes with the removal of noise components out of the frequency/phase variation range.

The reference signal, after undergoing the removal of the noise components out of the frequency/phase variation range of the reference signal forming the follow-up object in the band pass filter 1, is compared in phase with a signal from a group of voltage controlled oscillators (VCOs) in a phase comparator 2, and the phase comparator 2 outputs a voltage corresponding to (proportional to) the difference signal therebetween. This voltage passes through a low pass filter 3 where the elimination of its noise components takes place. The voltage after the elimination of the noise components is given as a drive voltage to the VCO group.

Also in this arrangement, a plurality of VCOs 9 to 11 are provided which have different voltage-frequency sensitivities from each other, thereby changing the gain of the PLL loop through the selection or switching among the VCOs 9 to 11. For the selection among the plurality of VCOs 9 to 11 to change the loop gain, a selection unit 8 is placed between these VCOs 9 to 11 and the phase comparator 2. For example, for increasing the loop gain, the selection unit 8 selects the output of a VCO with a high voltage-frequency sensitivity, and for decreasing the loop gain, the selection unit 8 selects the output of a VCO with a low voltage-frequency sensitivity. The selection unit 8 is controlled by a control unit 6, and the control unit 6 is designed to control the selection unit 8 in accordance with a noise power density (the amount of noise) contained in a reference signal inputted. In this connection, the control unit 6 and the selection unit 8 constitute a selection control unit for a change of the PLL loop gain.

A description will be given hereinbelow of a loop gain changing method, that is, VCO output selecting method.

As described above, the change of the loop gain causes a change of the follow-up characteristic with respect to the frequency/phase variation of the inputted reference signal. For the improvement of the follow-up characteristic, there is a need to increase the loop gain. On the other hand, the increase in the loop gain can increase the jitter of the VCO output occurring due to a noise component contained in the reference signal. Accordingly, when the noise power density contained in the reference signal is low, since the jitter of the VCO output signal stemming from the noise component introduced into the inputted reference signal is not large, the loop gain is increased through the selection of the output of a VCO with a high voltage-frequency sensitivity to provide higher follow-up characteristic with respect to the frequency/phase variation of the reference signal. On the other hand, when the noise power density contained in the reference signal is high, since the jitter of the VCO output signal stemming from the noise component introduced into the inputted reference signal becomes large, the loop gain is decreased through the selection of the output of a VCO with a low voltage-frequency sensitivity to reduce the jitter of the VCO output signal due to the noise components of the inputted reference signal.

Thus, although the use of only the low pass filter 3 in the PLL loop cannot achieve the sufficient removal of the high-frequency noise components, the additional employment of the band pass filter 1 with the steep frequency characteristic shown in FIG. 2 can sufficiently remove the noise components introduced into the reference signal constituting the PLL loop input. This can achieve the reduction of the jitter of a VCO output signal stemming from the noise components contained in the inputted reference signal.

In addition, the selection among the outputs of the VCOs with different voltage-frequency sensitivities controls the PLL loop gain, which can provide high follow-up characteristic with respect to the frequency/phase variation of a reference signal while reducing the jitter due to the noise introduced into the reference signal.

As described above, according to the fourth embodiment, the employment of the band pass filter 1 in the former stage of the phase comparator 2 can eliminate the unnecessary noise components out of the frequency/phase variation range of the reference signal forming the follow-up object from the PLL loop inputted reference signal, thereby reducing the jitter of a signal to be outputted from the voltage controlled oscillators, which realizes a PLL circuit providing less jitter even if much noise is introduced into the reference signal.

Moreover, the PLL loop gain is controlled through the selection of one of the outputs of the VCOs with different voltage-frequency sensitivities so that the higher follow-up characteristic is obtainable with respect to the frequency/phase variation of a reference signal while the less jitter due to the noise of the reference signal is achievable, thus realizing a PLL circuit which maximizes the followable reference signal frequency/phase variation range in accordance with the amount of noise contained in the reference signal while maintaining the jitter due to the noise to a constant allowable level.

(Fifth Embodiment)

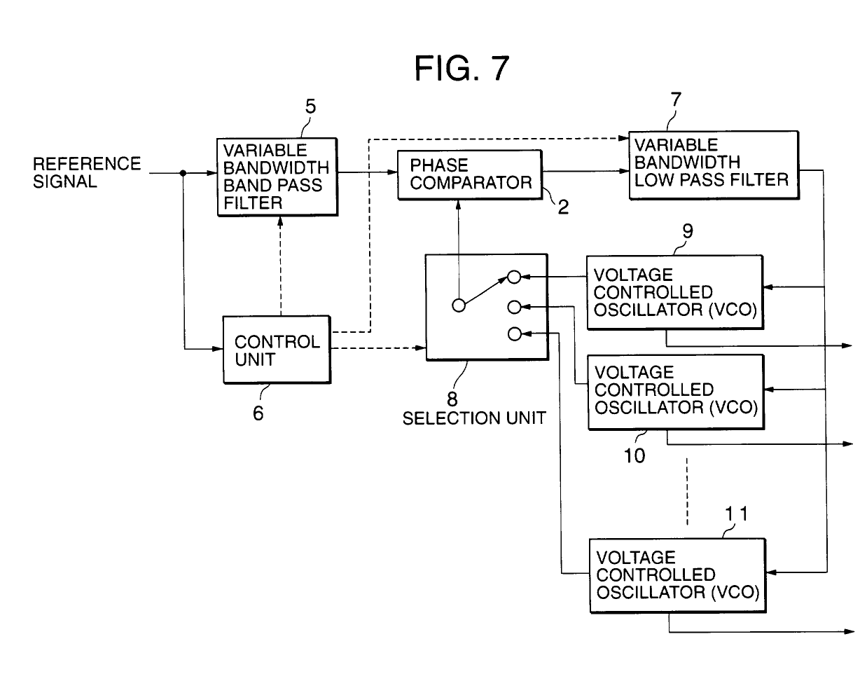

FIG. 7 is a block diagram showing an arrangement of a PLL circuit according to a fifth embodiment of the present invention. The fifth embodiment relates to a combination of the circuit arrangement according to the second embodiment and the circuit arrangement according to the third embodiment, and the voltage controlled oscillator (VCO) is replaced with voltage controlled oscillators (VCOs) 9, 10 and 11 having different voltage-frequency sensitivities, and a selection unit 8 and a control unit (selection control unit) 6 are additionally put to use.

Referring to FIG. 7, a description will be given hereinbelow of an operation of the PLL circuit according to the fifth embodiment.

A reference signal including noise, inputted to the PLL loop, is fed to a variable bandwidth band pass filter 5 where the elimination of its noise components takes place. The passband of the variable bandwidth band pass filter 5 is controlled in accordance with the density of noise power contained in a reference signal as shown in FIG. 4. That is, if the noise power density contained in the reference signal is low (noise power density B in FIG. 4), the jitter of the VCO output signal stemming from the noise components introduced into the inputted reference signal does not reach a large value, so the passband width is enlarged to widen the followable frequency/phase variation band on the reference signal. On the other hand, if the noise power density contained in the reference signal is high (noise power density A in FIG. 4), the jitter of the VCO output signal due to the noise components introduced into the inputted reference signal increases, so the passband width is narrowed to lower the jitter of the VCO output signal originating from the noise components introduced into the inputted reference signal.

The noise component removed reference signal from the variable bandwidth band pass filter 5 is compared in phase with a signal from the VCO in the phase comparator 2, and the phase comparator 2 outputs a voltage corresponding to (proportional to) the difference signal therebetween. This voltage undergoes further removal of the noise components when passing through the variable bandwidth low pass filter 7.

As well as the variable bandwidth band pass filter 5, the passband width of the variable bandwidth low pass filter 7 is widened when the density of noise power contained in the reference signal is low, for that the jitter of the VCO output signal originating from the noise components introduced into the inputted reference signal is not large. This enlarges the followable reference signal frequency/phase variation band.

On the other hand, if the density of noise power contained in the reference signal is high, the jitter of the VCO output signal originating from the noise components introduced into the inputted reference signal increases. For this reason, the jitter of the VCO output signal due to the noise components of the inputted reference signal is reduced by narrowing the passband width of the variable bandwidth low pass filter 7. The noise component removed voltage is given to the VCO section to function as a drive voltage.

In this case, a control unit 6 is made to control the passbands of the variable bandwidth band pass filter 5 and the variable bandwidth low pass filter 7. This control unit 6 also functions as a portion of a selection control unit as described below.

In addition, in this arrangement, as FIG. 7 shows, a plurality of VCOs 9 to 11 constituting the VCO group are provided which are made to have different voltage-frequency sensitivities, and the gain of the PLL loop is changed through the selection among these VCOs 9 to 11 with the different voltage-frequency sensitivities. For the selection among the VCOs 9 to 11 to change the loop gain, a selection unit 8 is placed between these VCOs 9 to 11 and the phase comparator 2. For example, for increasing the loop gain, the selection unit 8 selects the output of a VCO with a high voltage-frequency sensitivity, and for decreasing the loop gain, the selection unit 8 selects the output of a VCO with a low voltage-frequency sensitivity. The selection unit 8 is controlled by a control unit 6, and the control unit 6 is designed to control the selection unit 8 in accordance with a noise power density (the amount of noise) contained in a reference signal inputted. In this connection, the control unit 6 and the selection unit 8 constitute a selection control unit for a change of the PLL loop gain.

A description will be given hereinbelow of a loop gain changing method, that is, VCO output selecting method.

A change of the loop gain causes a change of the follow-up characteristic with respect to the frequency/phase variation of the inputted reference signal. For the improvement of the follow-up characteristic, there is a need to increase the loop gain. On the other hand, the increase in the loop gain can increase the jitter of the VCO output occurring due to a noise component contained in the reference signal.

Accordingly, when the noise power density contained in the reference signal is low, since the jitter of the VCO output signal stemming from the noise component introduced into the inputted reference signal is not large, the output of a VCO with a high voltage-frequency sensitivity is selected to increase the loop gain. This can provide higher follow-up characteristic with respect to the frequency/phase variation of the reference signal.

On the other hand, when the noise power density contained in the reference signal is high, since the jitter of the VCO output signal stemming from the noise component introduced into the inputted reference signal becomes large, the output of a VCO with a low voltage-frequency sensitivity is selected to decrease the loop gain. This can reduce the jitter of the VCO output signal stemming from the noise components of the inputted reference signal.

Thus, although the use of only the variable bandwidth low pass filter 7 in the PLL loop cannot achieve the sufficient removal of the high-frequency noise components, the additional employment of the variable bandwidth band pass filter 5 can sufficiently remove the noise components introduced into the reference signal constituting the PLL loop input. This can achieve the reduction of the jitter of a VCO output signal stemming from the noise components contained in the inputted reference signal.

In addition, in this configuration, the passband of the variable bandwidth band pass filter 5 and/or the variable bandwidth low pass filter 7 is controlled in accordance with a density of noise power contained in the reference signal. This can enlarge the followable reference signal frequency/phase variation range while reducing the jitter occurring due to noise introduced into the reference signal.

Still additionally, the selection among the outputs of the VCOs with different voltage-frequency sensitivities controls the PLL loop gain, which can provide high follow-up characteristic with respect to the frequency/phase variation of a reference signal while reducing the jitter due to the noise introduced into the reference signal.

As described above, according to the fifth embodiment, the variable bandwidth band pass filter 5 provided in the former stage of the phase comparator 2 removes the noise components in unnecessary bands, existing in the reference signal forming the PLL loop input, other than the frequency/phase variation range of the reference signal forming the follow-up object, thus reducing the jitter of a signal to be outputted from the voltage controlled oscillator 4 to realize a PLL circuit with less jitter even if much noise exists in the reference signal.

Moreover, the PLL loop gain is controlled through the selection of one of the outputs of the VCOs with different voltage-frequency sensitivities so that the higher follow-up characteristic is obtainable with respect to the frequency/phase variation of a reference signal while the less jitter due to the noise of the reference signal is achievable, thus realizing a PLL circuit which maximizes the followable reference signal frequency/phase variation range in accordance with the amount of noise contained in the reference signal while maintaining the jitter due to the noise to a constant allowable level.

(Sixth Embodiment)

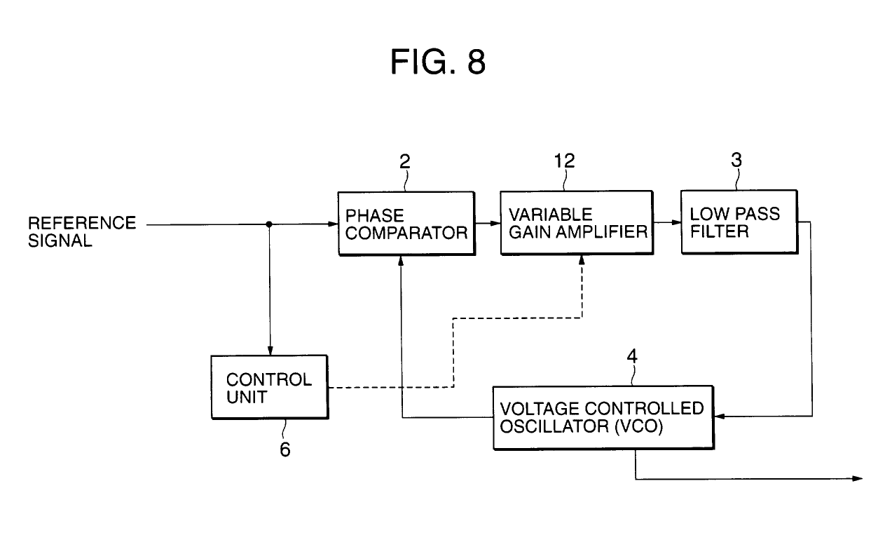

FIG. 8 is a block diagram showing an arrangement of a PLL circuit according to a sixth embodiment of the present invention.

A feature of the sixth embodiment is that a variable gain amplifier 12 is provided in a latter stage of a phase comparator 2 and a control unit 6 is provided to control the gain of the variable gain amplifier 12 in accordance with an amount of noise introduced into a reference signal.

A description will be given hereinbelow of an operation of the PLL circuit according to the sixth embodiment.

A reference signal containing noise, inputted to the PLL loop, is compared in phase with a signal from a voltage controlled oscillator (VCO) 4 in the phase comparator 2, and the phase comparator 2 outputs a voltage corresponding to the difference signal therebetween. This voltage is amplified in the variable gain amplifier 12, before advancing to a low pass filter 3 and the VCO 4.

A description will be given hereinbelow of a method of varying the gain of the variable gain amplifier 12.

As described above, a change of the loop gain causes a change of the follow-up characteristic with respect to the frequency/phase variation of the inputted reference signal. For the improvement of the follow-up characteristic, there is a need to increase the loop gain. On the other hand, the increase in the loop gain can increase the jitter of the VCO output occurring due to a noise component contained in the reference signal. Accordingly, when the noise power density contained in the reference signal is low, since the jitter of the VCO output signal stemming from the noise component introduced into the inputted reference signal is not large, the gain of the variable gain amplifier 12 is stepped up to increase the loop gain, thereby providing higher follow-up characteristic with respect to the frequency/phase variation of the reference signal. On the other hand, when the noise power density contained in the reference signal is high, since the jitter of the VCO output signal stemming from the noise component introduced into the inputted reference signal becomes large, the gain of the variable gain amplifier 12 is lowered to decrease the loop gain, thereby reducing the jitter of the VCO output signal stemming from the noise components of the inputted reference signal.

The voltage proportional to the difference signal after passing through the variable gain amplifier 12 enters the low pass filter 3 where the elimination of its noise components takes place. The voltage undergoing the elimination of the noise components is given as a drive signal to the VCO 4.

Since the PLL loop gain is controlled by the variable gain amplifier 12 in this way, it is possible to enhance the follow-up characteristic with respect to the frequency/phase variation of a reference signal while reducing the jitter arising from noise introduced into the reference signal.

As described above, according to the sixth embodiment, the PLL loop gain is controlled by the variable gain amplifier 12 so that the higher follow-up characteristic is obtainable with respect to the frequency/phase variation of a reference signal while the less jitter due to the noise of the reference signal is achievable, thus realizing a PLL circuit which maximizes the followable reference signal frequency/phase variation range in accordance with the amount of noise contained in the reference signal while maintaining the jitter due to the noise to a constant allowable level.

(Seventh Embodiment)

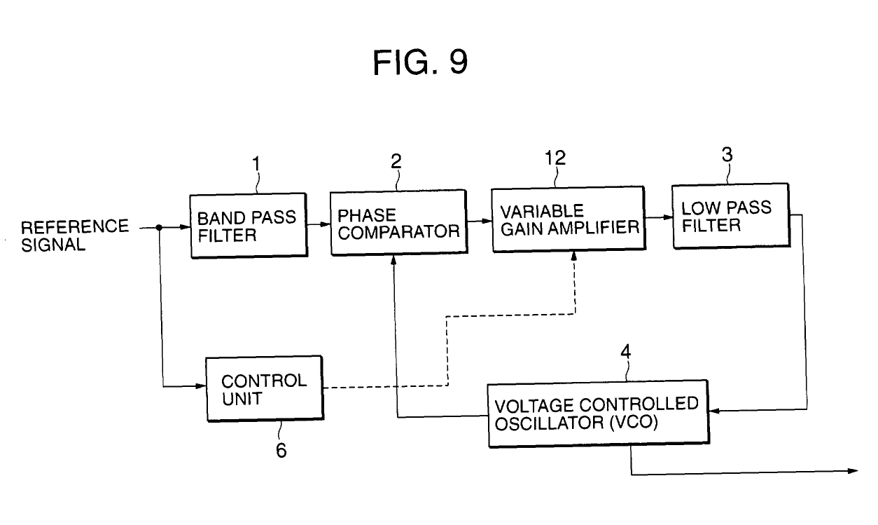

FIG. 9 is a block diagram showing an arrangement of a PLL circuit according to a seventh embodiment of the present invention. The seventh embodiment shown in FIG. 9 relates to a combination of the circuit arrangement according to the first embodiment and the circuit arrangement according to the sixth embodiment. That is, in the circuit arrangement according to the sixth embodiment shown in FIG. 8, a band pass filter 1 is provided in a former stage of a phase comparator 2.

A description will be given hereinbelow of an operation of the PLL circuit according to the seventh embodiment.

A reference signal containing noise, inputted to the PLL loop, is fed to the band pass filter 1 where the removal of its noise component takes place. Similarly, the characteristic of this band pass filter 1 is as shown in FIG. 2. That is, the filter characteristic shows a steep frequency characteristic which has a bandwidth accepting the frequency/phase variation of a reference signal forming a follow-up object and which eliminates high-frequency noise components out of the frequency/phase variation range.

After the elimination of the high-frequency noise components out of the reference signal frequency/phase variation range in the band pass filter 1, the reference signal is compared in phase with a signal from a voltage controlled oscillator (VCO) 4 in the phase comparator 2, and the phase comparator 2 outputs a voltage corresponding to the difference signal therebetween. This voltage is amplified in a variable gain amplifier 12, before advancing to a low pass filter 3 and the VCO 4.

A description will be given hereinbelow of a method of controlling the gain of the variable gain amplifier 12.

As described above, a change of the loop gain causes a change of the follow-up characteristic with respect to the frequency/phase variation of the inputted reference signal. For the improvement of the follow-up characteristic, there is a need to increase the loop gain. On the other hand, the increase in the loop gain can increase the jitter of the VCO output occurring due to a noise component contained in the reference signal. Accordingly, when the noise power density contained in the reference signal is low, since the jitter of the VCO output signal stemming from the noise component introduced into the inputted reference signal is not large, the gain of the variable gain amplifier 12 is stepped up to increase the loop gain, thereby providing higher follow-up characteristic with respect to the frequency/phase variation of the reference signal. On the other hand, when the noise power density contained in the reference signal is high, since the jitter of the VCO output signal stemming from the noise component introduced into the inputted reference signal becomes large, the gain of the variable gain amplifier 12 is lowered to decrease the loop gain, thereby reducing the jitter of the VCO output signal stemming from the noise components of the inputted reference signal.

The voltage proportional to the difference signal after passing through the variable gain amplifier 12 enters the low pass filter 3 where the elimination of its noise components takes place. The voltage undergoing the elimination of the noise components is given as a drive signal to the VCO 4.

Thus, although the use of only the low pass filter 3 in the PLL loop cannot achieve the sufficient removal of the high-frequency noise components, the additional employment of the band pass filter 1 can sufficiently remove the noise components introduced into the reference signal constituting the PLL loop input. Moreover, this can achieve the reduction of the jitter of an output signal of the VCO 4 stemming from the noise components contained in the inputted reference signal.

In addition, the control of the PLL loop gain by the variable gain amplifier 12 can enhance the follow-up characteristic with respect to the frequency/phase variation of a reference signal while reducing the jitter arising from noise introduced into the reference signal.

As described above, according to the seventh embodiment, the band pass filter 1 provided in the former stage of the phase comparator 2 removes the noise components in unnecessary bands, existing in the reference signal forming the PLL loop input, other than the frequency/phase variation range of the reference signal forming the follow-up object, thus reducing the jitter of a signal to be outputted from the VCO 4 to realize a PLL circuit with less jitter even if much noise exists in the reference signal.

Furthermore, since the PLL loop gain is controlled by the variable gain amplifier 12, it is possible to enhance the follow-up characteristic with respect to the frequency/phase variation of a reference signal while reducing the jitter occurring due to noise of the reference signal, thus realizing a PLL circuit which maximizes the followable reference signal frequency/phase variation range in accordance with the amount of noise introduced into the reference signal in a state where the jitter arising due to noise is kept to a constant allowable level.

(Eighth Embodiment)

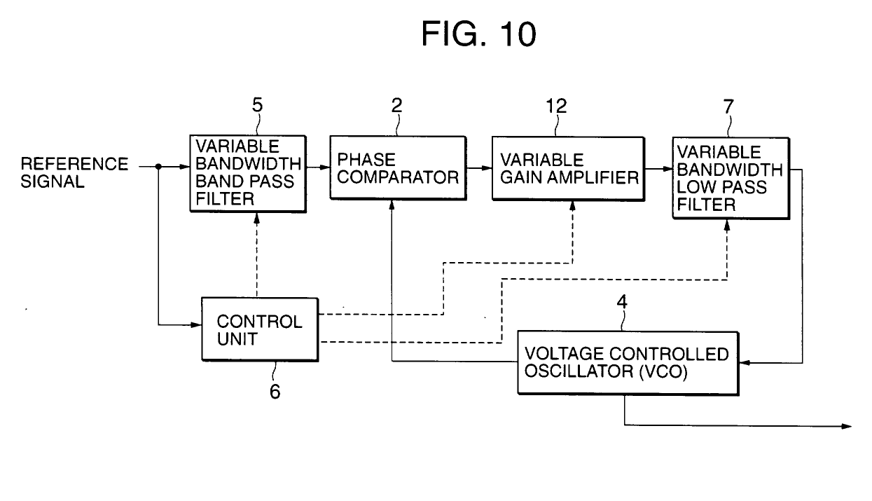

FIG. 10 is a block diagram showing an arrangement of a PLL circuit according to an eighth embodiment of the present invention. This eighth embodiment relates to a combination of the circuit arrangement according to the second embodiment and the circuit arrangement according to the sixth embodiment, that is, the band pass filter is constructed as a variable bandwidth band pass filter 5 and the low pass filter is constructed as a variable bandwidth low pass filter 7. A control unit 6 controls the variable bandwidth band pass filter 5 and the variable bandwidth low pass filter 7 in accordance with a density of noise power contained in the reference signal.

A description will be given hereinbelow of an operation of the PLL circuit according to the eighth embodiment.

When a reference signal containing noise is inputted to the PLL loop, the variable bandwidth band pass filter 5 removes that noise components. The characteristic of the variable bandwidth band pass filter 5 is as shown in FIG. 4. The passband of the variable bandwidth band pass filter 5 is controlled on the basis of a density of noise power contained in the reference signal. That is, if the noise power density contained in the reference signal is low (noise power density B in FIG. 4), the jitter of an output signal of the VCO 4 stemming from the noise components introduced into the inputted reference signal does not reach a large value, so the passband width is enlarged to widen the followable frequency/phase variation band on the reference signal. On the other hand, if the noise power density contained in the reference signal is high (noise power density A in FIG. 4), the jitter of an output signal of the VCO 4 stemming from the noise components introduced into the inputted reference signal increases, so the passband width is reduced to lower the jitter of the VCO output signal originating from the noise components introduced into the inputted reference signal.

The noise component removed reference signal from the variable bandwidth band pass filter 5 is compared in phase with a signal from the VCO 4 in the phase comparator 2, and the phase comparator 2 outputs a voltage corresponding to the difference signal therebetween. This voltage is amplified by a variable gain amplifier 12.

A description will be given hereinbelow of a method of controlling the gain of the variable gain amplifier 12.

As described above, a change of the loop gain causes a change of the follow-up characteristic with respect to the frequency/phase variation of the inputted reference signal. For the improvement of the follow-up characteristic, there is a need to increase the loop gain. On the other hand, the increase in the loop gain can increase the jitter of the VCO output occurring due to a noise component contained in the reference signal. Accordingly, when the noise power density contained in the reference signal is low, since the jitter of the VCO output signal stemming from the noise component introduced into the inputted reference signal is not large, the gain of the variable gain amplifier 12 is stepped up to increase the loop gain, thereby providing higher follow-up characteristic with respect to the frequency/phase variation of the reference signal. On the other hand, when the noise power density contained in the reference signal is high, since the jitter of the VCO output signal stemming from the noise component introduced into the inputted reference signal becomes large, the gain of the variable gain amplifier 12 is lowered to decrease the loop gain, thereby reducing the jitter of the VCO output signal stemming from the noise components of the inputted reference signal.

The voltage proportional to the difference signal after passing through the variable gain amplifier 12 enters the variable bandwidth low pass filter 7 where the elimination of its noise components takes place. As well as the variable bandwidth band pass filter 5, if the noise power density contained in the reference signal is low, since the jitter of the VCO output signal arising due to the noise components introduced into the reference signal is not large, the passband of the variable bandwidth low pass filter 7 is widened to enlarge the followable reference signal frequency/phase variation range. On the other hand, if the noise power density contained in the reference signal is high, the jitter of an output signal of the VCO 4 stemming from the noise components introduced into the inputted reference signal increases, so the passband width is reduced to lower the jitter of the VCO output signal originating from the noise components introduced into the inputted reference signal. The voltage undergoing the elimination of the noise components is given as a drive signal to the VCO 4.

Thus, although only the variable bandwidth low pass filter 7 cannot achieve the sufficient removal of the high-frequency noise components, the additional employment of the variable bandwidth band pass filter 7 can sufficiently achieve the sufficient removal of the noise components introduced into the reference signal constituting the PLL loop input. This can achieve the reduction of the jitter of an output signal of the VCO 4 stemming from the noise components contained in the inputted reference signal.

In addition, the passband of the variable bandwidth band pass filter 5 and/or the variable bandwidth low pass filter 7 is controlled by the control unit 6 in accordance with a density of noise power contained in the reference signal, thereby enlarging the followable frequency/phase variation range on the reference signal while reducing the jitter occurring due to noise.

Still additionally, since the PLL loop gain is controlled by the variable gain amplifier 12, it is possible to enhance the follow-up characteristic with respect to the frequency/phase variation of a reference signal while reducing the jitter arising from the noise introduced into the reference signal.

As described above, according to the eighth embodiment, the variable bandwidth band pass filter 5 provided in the former stage of the phase comparator 2 removes the noise components in unnecessary bands, existing in the reference signal forming the PLL loop input, other than the frequency/phase variation range of the reference signal forming the follow-up object, thus reducing the jitter of a signal to be outputted from the voltage controlled oscillator 4 to realize a PLL circuit with less jitter even if much noise exists in the reference signal.

In addition, since the passband of the variable bandwidth band pass filter 5 and/or the variable bandwidth low pass filter 7 is controlled in accordance with a density of noise power contained in a reference signal, it is possible to enlarge the followable frequency/phase variation range on the reference signal while reducing the jitter occurring due to noise.

Still additionally, since the PLL loop gain is controlled by the variable gain amplifier 12, it is possible to enhance the follow-up characteristic with respect to the frequency/phase variation of a reference signal while reducing the jitter arising from noise introduced into the reference signal, thus realizing a PLL circuit which maximizes the followable reference signal frequency/phase variation range in accordance with the amount of noise introduced into the reference signal in a state where the jitter arising due to noise is kept to a constant allowable level.

It should be understood that the present invention is not limited to the above-described embodiments, and that it is intended to cover all changes and modifications of the embodiments of the invention herein which do not constitute departures from the spirit and scope of the invention.

What is claimed is:

1. A PLL circuit comprising:
a voltage controlled oscillator;
a low pass filter;
a phase comparator for comparing an output of said voltage controlled oscillator with a reference signal to control a voltage to said voltage controlled oscillator on the basis of an output of said phase comparator, passed through said low pass filter, so that said output of said voltage controlled oscillator and said reference signal agree with each other; and
a band pass filter provided in a former stage of said phase comparator for eliminating a noise component contained in said reference signal, said band pass filter having a bandwidth corresponding to a frequency/phase variation range of said reference signal.

2. The PLL circuit according to claim 1, wherein said band pass filter is a variable bandwidth band pass filter whose bandwidth is variable in accordance with a control signal and said low pass filter is a variable bandwidth low pass filter whose bandwidth is variable in accordance with a control signal, and a control unit is provided to output said control signals for controlling said bandwidths of said variable bandwidth band pass filter and said variable bandwidth low pass filter, with said control unit being made to control said bandwidths of said variable bandwidth band pass filter and said variable bandwidth low pass filter as a function of an amount of noise contained in said reference signal.

3. A PLL circuit comprising:
a voltage controlled oscillator, said voltage controlled oscillator being composed of a plurality of voltage controlled oscillators different in voltage-frequency sensitivity from each other;
a low pass filter;
a phase comparator for comparing an output of said voltage controlled oscillator with a reference signal to control a voltage to said voltage controlled oscillator on the basis of an output of said phase comparator, passed through said low pass filter, so that said output of said voltage controlled oscillator and said reference signal agree with each other; and
a selection control unit for selectively switching outputs of said plurality of voltage controlled oscillators, with said selection control unit being made to select said outputs of said plurality of voltage controlled oscillators on the basis of an amount of noise contained in said reference signal for changing a gain of a PLL loop.

4. The PLL circuit according to claim 3, further comprising a band pass filter provided in a former stage of said phase comparator for eliminating a noise component contained in said reference signal, said band pass filter having a bandwidth corresponding to a frequency/phase variation range of said reference signal.

5. The PLL circuit according to claim 4, wherein said band pass filter is a variable bandwidth band pass filter whose bandwidth is variable in accordance with a control signal and said low pass filter is a variable bandwidth low pass filter whose bandwidth is variable in accordance with a control signal, and said selection control unit outputs said control signals for controlling said bandwidths of said variable bandwidth band pass filter and said variable bandwidth low pass filter, with said selection control unit being made to control said bandwidths of said variable bandwidth band pass filter and said variable bandwidth low pass filter as a function of an amount of noise contained in said reference signal.

6. A PLL circuit comprising:
a voltage controlled oscillator;
a low pass filter;
a phase comparator for comparing an output of said voltage controlled oscillator with a reference signal to control a voltage to said voltage controlled oscillator on the basis of an output of said phase comparator, passed through said low pass filter, so that said output of said voltage controlled oscillator and said reference signal agree with each other;
a variable gain amplifier provided in a latter stage of said phase comparator; and
a control unit for controlling said variable gain amplifier, with said control unit being designed to control a gain of said variable gain amplifier on the basis of an amount of noise contained in said reference signal for changing a PLL loop gain.

7. The PLL circuit according to claim 6, further comprising a band pass filter provided in a former stage of said phase comparator for eliminating a noise component contained in said reference signal, said band pass filter having a bandwidth corresponding to a frequency/phase variation range of said reference signal.

8. The PLL circuit according to claim 7, wherein said band pass filter is a variable bandwidth band pass filter whose bandwidth is variable in accordance with a control signal and said low pass filter is a variable bandwidth low pass filter whose bandwidth is variable in accordance with a control signal, and said control unit outputs said control signals for controlling said bandwidths of said variable bandwidth band pass filter and said variable bandwidth low pass filter, with said control unit being made to control said bandwidths of said variable bandwidth band pass filter and said variable bandwidth low pass filter as a function of an amount of noise contained in said reference signal.

9. A PLL circuit comprising:
a voltage controlled oscillator, said voltage controlled oscillator being composed of a plurality of voltage controlled oscillators different in voltage-frequency sensitivity from each other;
a low pass filter;
a phase comparator for comparing an output of said voltage controlled oscillator with a reference signal to control a voltage to said voltage controlled oscillator on the basis of an output of said phase comparator, passed through said low pass filter, so that said output of said voltage controlled oscillator and said reference signal agree with each other; and
a selection control unit coupled to said reference signal for selectively switching outputs of said plurality of voltage controlled oscillators as a function of a noise power density in said reference signal for changing a gain of a PLL loop, said selection control unit selecting said output of said voltage controlled oscillator having a higher voltage-frequency sensitivity for increasing said PLL loop gain when said noise power density is below a predetermined value and selecting said output of said voltage controlled oscillator having a lower voltage-frequency sensitivity for decreasing said PLL loop gain when said noise power density is equal to or more than said predetermined value.

10. The PLL circuit according to claim 9, further comprising a variable bandwidth band pass filter variable in bandwidth and provided in a former stage of said phase comparator for eliminating a noise component contained in said reference signal, said selection control unit controlling said bandwidth of said variable bandwidth band pass filter in accordance with said noise power density so that said bandwidth of said variable bandwidth band pass filter is widened when said noise power density is below a predetermined value and said bandwidth of said variable bandwidth band pass filter is narrowed when said noise power density is equal to or more than said predetermined value.
